(19) United States
(12) Patent Application Publication
(10) Pub. No.: US 2019/0146339 A1
(43) Pub. Date: May 16, 2019

(54) PHOTOSENSITIVE CONDUCTIVE PASTE, METHOD FOR MANUFACTURING MULTILAYER ELECTRONIC COMPONENT, AND MULTILAYER ELECTRONIC COMPONENT

(71) Applicant: Murata Manufacturing Co., Ltd., Kyoto-tu (JP)

(72) Inventor: Kenta KONDO, Nagaokakyo-shi (JP)

(73) Assignee: Murata Manufacturing Co., Ltd., Kyoto-fu (JP)

(21) Appl. No.: 16/228,584

(22) Filed: Dec. 20, 2018

Related U.S. Application Data
(63) Continuation of application No. PCT/JP2017/025940, filed on Jul. 18, 2017.

(30) Foreign Application Priority Data
Jul. 21, 2016 (JP) 2016-143491

(51) Int. Cl. G03F 7/033; C09D 5/24; C09D 4/00; G03F 7/031; G03F 7/16; G03F 7/20; G03F 7/26; H01B 1/22; H01F 27/28; H01F 41/04; H01F 41/12; H01F 27/32

(52) U.S. Cl. CPC G03F 7/033; C09D 5/24; C09D 4/00; G03F 7/031; G03F 7/16; G03F 7/20; H01F 2027/2809; H01B 1/22; H01F 27/2804; H01F 41/043; H01F 41/122; H01F 27/323; G03F 7/26

(57) ABSTRACT

A photosensitive conductive paste according to the present disclosure contains a metal powder, a metal resinate containing a metal having a higher melting point than the metal powder, and a photosensitive organic component, in which the content of the metal resinate, in terms of metal, with respect to the metal powder is 0.0025% by weight or more and 1.0% by weight or less (i.e., from 0.0025% by weight to 1.0% by weight), and the content of the metal powder in the photosensitive conductive paste is 68% by weight or more and 88% by weight or less (i.e., from 68% by weight to 88% by weight).

### CROSS-REFERENCE TO RELATED APPLICATIONS

This application claims benefit of priority to International Patent Application No. PCT/JP2017/025940, filed Jul. 18, 2017, and to Japanese Patent Application No. 2016-143491, filed Jul. 21, 2016, the entire contents of each are incorporated herein by reference.

### BACKGROUND

### Technical Field

The present disclosure relates to a photosensitive conductive paste, a method for manufacturing a multilayer electronic component, and a multilayer electronic component.

### Background Art

In recent years, a method for manufacturing a multilayer electronic component, such as a multilayer ceramic circuit board, in which conductor layers are formed by using a photosensitive conductive paste, has been widely used. Japanese Unexamined Patent Application Publication No. 2009-237245 discloses a photosensitive conductive paste that contains an organic component containing a photosensitive organic component, and conductive powder, in which the conductive powder contains conductive powder having a particle size of 2 μm or less within the range from 30% to 50% by mass, the organic component contains an unsaturated fatty acid, and the content of the unsaturated fatty acid in the photosensitive conductive paste is within the range from 0.5% to 5% by mass.

### SUMMARY

Regarding the photosensitive conductive paste according to Japanese Unexamined Patent Application Publication No. 2009-237245, it is described that by controlling the content of conductive powder having a particle size of 2 μm or less in the conductive powder, good light transmittance is guaranteed, and that by adding an appropriate amount of an unsaturated fatty acid, occurrence of development residues is suppressed, which, as a result, makes it possible to form a conductive pattern having high resolution at the level of 10 μm.

However, in the case where the photosensitive conductive paste according to Japanese Unexamined Patent Application Publication No. 2009-237245 is used as a conductive paste for forming conductor layers in manufacturing a multilayer electronic component in which inner electrodes, i.e., conductor layers, are stacked together with an insulation layer interposed therebetween, interlayer separation, referred to as delamination, occurs between the conductor layer and the insulation layer because the photosensitive conductive paste exhibits greater shrinkage during firing than a ceramic which is a constituent material of the insulation layer.

The present disclosure thus provides a photosensitive conductive paste, in which even in the case where the photosensitive conductive paste is used to form conductor layers in manufacturing a multilayer electronic component including the conductor layers which are stacked together with an insulation layer interposed therebetween, occurrence of delamination between the conductor layer and the insulation layer can be suppressed, and a fine conductive pattern can be formed. The present disclosure also provides a method for manufacturing a multilayer electronic component including a step of forming a conductor layer by using the photosensitive conductive paste, and a multilayer electronic component including conductor layers formed by using the photosensitive conductive paste.

A photosensitive conductive paste according to the present disclosure contains a metal powder, a metal resinate containing a metal having a higher melting point than the metal powder, and a photosensitive organic component, in which the content of the metal resinate, in terms of metal, with respect to the metal powder is 0.0025% by weight or more and 1.0% by weight or less (i.e., from 0.0025% by weight to 1.0% by weight), and the content of the metal powder in the photosensitive conductive paste is 68% by weight or more and 88% by weight or less (i.e., from 68% by weight to 88% by weight).

In the photosensitive conductive paste according to the present disclosure, by incorporating the metal resinate containing a metal having a higher melting point than the metal powder, the metal resinate acts as a firing shrinkage inhibitor. Therefore, when a multilayer electronic component is manufactured, shrinkage during firing of a conductor layer is suppressed, and occurrence of delamination between a conductor layer and an insulation layer can be suppressed. Furthermore, the resinate is usually in the form of a liquid, and by setting the content of the metal resinate, in terms of metal, with respect to the metal powder at 0.0025% by weight or more and 1.0% by weight or less (i.e., from 0.0025% by weight to 1.0% by weight), light scattering is unlikely to occur. Therefore, light transmittance is unlikely to decrease during formation of a conductive pattern by photolithography, and a fine conductive pattern with a line width of 50 μm or less can be formed. Furthermore, by using, as a firing shrinkage inhibitor, the resinate that is usually in the form of a liquid, in comparison with the case where a solid (powder) firing shrinkage inhibitor is used, paste dispersibility is improved. Therefore, the conductor layer is likely to shrink isotropically, and satisfactory line linearity can be easily obtained. As described above, by using the photosensitive conductive paste according to the present disclosure, while it is possible to form a fine conductive pattern, it is possible to suppress occurrence of delamination between the conductor layer and the insulation layer.

In the photosensitive conductive paste according to the present disclosure, preferably, the metal powder is a Ag powder or Cu powder. Ag and Cu have low resistance and, therefore, are particularly suitable when used for multilayer electronic components.

As the melting point of the metal contained in the metal resinate becomes much higher than that of the metal powder, by using a smaller amount of the metal resinate, the effect of suppressing shrinkage during firing of the conductor layer can be easily obtained. Therefore, in the photosensitive conductive paste according to the present disclosure, preferably, the difference between the melting point of the metal contained in the metal resinate and the melting point of the metal powder is 121° C. or more.

In the photosensitive conductive paste according to the present disclosure, preferably, the metal contained in the metal resinate is one selected from the group consisting of Rh, Ni, Cu, Mn, and Zr. In the photosensitive conductive paste according to the present disclosure, preferably, the content of the metal powder in the photosensitive conductive paste is 80% by weight or more and 88% by weight or less (i.e., from 80% by weight to 88% by weight). In this case, occurrence of delamination between the conductor layer and the insulation layer can be further suppressed.

In the photosensitive conductive paste according to the present disclosure, preferably, the content of the metal resinate, in terms of metal, with respect to the metal powder is 0.005% by weight or more. In this case, occurrence of delamination between the conductor layer and the insulation layer can be further suppressed.

In the photosensitive conductive paste according to the present disclosure, preferably, the content of the metal resinate, in terms of metal, with respect to the metal powder is 0.5% by weight or less. In this case, a fine conductive pattern with a line width of 40 μm or less can be formed.

In the photosensitive conductive paste according to the present disclosure, preferably, the content of the metal resinate, in terms of metal, with respect to the metal powder is 0.1% by weight or less. In this case, a fine conductive pattern with a line width of 20 μm or less can be formed.

In the photosensitive conductive paste according to the present disclosure, preferably, the content of the metal resinate, in terms of metal, with respect to the metal powder is 0.04% by weight or less. In this case, a fine conductive pattern with a line width of 10 μm or less can be formed.

A method for manufacturing a multilayer electronic component according to the present disclosure includes a step of integrally firing a multilayer body which includes a conductor layer formed by using the photosensitive conductive paste according to the present disclosure and an insulation layer formed by using a photosensitive insulating paste containing an insulating inorganic component and a photosensitive organic component. In the method for manufacturing a multilayer electronic component according to the present disclosure, by forming the conductor layer by using the photosensitive conductive paste according to the present disclosure, occurrence of delamination between the conductor layer and the insulation layer can be suppressed, and it is possible to manufacture a highly reliable multilayer electronic component.

A multilayer electronic component according to the present disclosure includes conductor layers obtained by firing the photosensitive conductive paste according to the present disclosure. The conductor layers are stacked together with an insulation layer obtained by firing a photosensitive insulating paste containing an insulating inorganic component and a photosensitive organic component interposed therebetween.

In the multilayer electronic component according to the present disclosure, since the conductor layer is formed by using the photosensitive conductive paste according to the present disclosure, occurrence of delamination between the conductor layer and the insulation layer is suppressed, and a highly reliable multilayer electronic component can be obtained.

According to the present disclosure, it is possible to provide a photosensitive conductive paste, in which even in the case where the photosensitive conductive paste is used to form conductor layers in manufacturing a multilayer electronic component including the conductor layers which are stacked together with an insulation layer interposed therebetween, occurrence of delamination between the conductor layer and the insulation layer can be suppressed, and a fine conductive pattern can be formed.

### BRIEF DESCRIPTION OF THE DRAWINGS

FIG. 1 is a perspective view schematically showing an example of a method for manufacturing a multilayer electronic component according to the present disclosure; and

FIG. 2 is a perspective view schematically showing an external structure of a multilayer electronic component manufactured by the manufacturing method shown in FIG. 1.

### DETAILED DESCRIPTION

Descriptions will be made below on a photosensitive conductive paste, a method for manufacturing a multilayer electronic component, and a multilayer electronic component according to the present disclosure. However, the present disclosure is not limited to the embodiments described below, and can be appropriately changed within the range not departing from the gist of the present disclosure. Note that a combination of two or more preferred embodiments described below is also covered by the present disclosure.

[Photosensitive Conductive Paste]

A photosensitive conductive paste according to the present disclosure contains a metal powder, a metal resinate, and a photosensitive organic component. The metal powder incorporated in the photosensitive conductive paste according to the present disclosure is not particularly limited, but is preferably a Ag powder or Cu powder.

The content of the metal powder in the photosensitive conductive paste is 68% by weight or more and 88% by weight or less (i.e., from 68% by weight to 88% by weight). From the standpoint of suppressing shrinkage during firing of a conductor layer and suppressing occurrence of delamination between a conductor layer and an insulation layer, preferably, the content of the metal powder is 80% by weight or more and 88% by weight or less (i.e., from 80% by weight to 88% by weight).

The average particle size of the metal powder is not particularly limited. From the standpoint of forming a fine conductive pattern, preferably, the average particle size of the metal powder is 1.0 μm or more and 5.0 μm or less (i.e., from 1.0 μm to 5.0 μm). The average particle size of the metal powder may be obtained, for example, by a laser diffraction scattering method in which, by using a particle size distribution measuring device MT3300-EX manufactured by MicrotracBEL Corp., the particle size distribution in the range of 0.02 to 1,400 μm is determined, and the number-average particle size is calculated and defined as the average particle size. Regarding a glass powder and a ceramic aggregate, which will be described later, the average particle size is obtained in the same manner.

The metal resinate incorporated in the photosensitive conductive paste according to the present disclosure contains a metal having a higher melting point than the metal powder. The photosensitive conductive paste according to the present disclosure may contain two or more metal resinates.

The metal resinate is a compound represented by the general formula (1) below.

M-X—R (1)

In the general formula (1), M represents a metal, X represents oxygen, nitrogen, or sulfur, and R represents an alkyl group. The compound represented by the general formula (1) is referred to as the “metal M-containing metal resinate”. Examples of the metal contained in the metal resinate include Rh, Ni, Cu, Mn, and Zr. Examples of the metal resinate include a metal octanoate, a metal naphthenate, a metal 2-ethylhexanoate, a metal sulfonate, a metal mercaptide, and an alkoxy metal compound.

In the photosensitive conductive paste according to the present disclosure, the metal contained in the metal resinate is not particularly limited as long as it has a higher melting point than the metal powder. As the melting point of the metal contained in the metal resinate becomes much higher than that of the metal powder, by using a smaller amount of the metal resinate, the effect of suppressing shrinkage during firing of the conductor layer can be easily obtained. Therefore, the difference between the melting point of the metal contained in the metal resinate and the melting point of the metal powder is preferably as large as possible, and specifically, is preferably 121° C. or more. For example, in the case where the metal powder is a Ag powder, the metal contained in the metal resinate is preferably one selected from the group consisting of Rh, Ni, Cu, Mn, and Zr. In the case where the metal powder is a Cu powder, the metal contained in the metal resinate is preferably one selected from the group consisting of Rh, Ni, Mn, and Zr.

The upper limit of the difference between the melting point of the metal contained in the metal resinate and the melting point of the metal powder is not particularly limited. For example, in the case where the metal resinate is a Ru resinate and the metal powder is a Ag powder, the difference in the melting point is 1,348° C. Therefore, the difference between the melting point of the metal contained in the metal resinate and the melting point of the metal powder is preferably 1,348° C. or less.

In the photosensitive conductive paste according to the present disclosure, the content of the metal resinate, in terms of metal, with respect to the metal powder is 0.0025% by weight or more and 1.0% by weight or less (from 0.0025% by weight to 1.0% by weight). From the standpoint of suppressing occurrence of delamination between the conductor layer and the insulation layer, the content of the metal resinate, in terms of metal, with respect to the metal powder is preferably 0.005% by weight or more. On the other hand, from the standpoint of forming a fine conductive pattern, the content of the metal resinate, in terms of metal, with respect to the metal powder is preferably 0.5% by weight or less, more preferably 0.1% by weight or less, and still more preferably 0.04% by weight or less.

In the photosensitive conductive paste, the content of the metal resinate, in terms of metal, is an amount of the metal constituting the metal resinate contained in the photosensitive conductive paste. That is, in the photosensitive conductive paste according to the present disclosure, the amount of the metal constituting the metal resinate, with respect to the metal powder, is 0.0025% by weight or more and 1.0% by weight or less (i.e., from 0.0025% by weight to 1.0% by weight). Specifically, the amount of the metal selected from the group consisting of Rh, Ni, Cu, Mn, and Zr, with respect to the metal powder, is preferably 0.0025% by weight or more and 1.0% by weight or less (i.e., from 0.0025% by weight to 1.0% by weight). From the standpoint of suppressing occurrence of delamination between the conductor layer and insulation layer, the amount of the metal constituting the metal resinate, with respect to the metal powder, is preferably 0.005% by weight or more. From the standpoint of forming a fine conductive pattern, the content of the metal resinate, in terms of metal, with respect to the metal powder is preferably 0.5% by weight or less, more preferably 0.1% by weight or less, and still more preferably 0.04% by weight or less.

The photosensitive conductive paste according to the present disclosure contains, as the photosensitive organic component, for example, an alkali-soluble polymer, a photosensitive monomer, and a photopolymerization initiator. As the alkali-soluble polymer, for example, an acrylic polymer having a carboxyl group at a side chain thereof can be used. The acrylic polymer having a carboxyl group at a side chain thereof can be produced, for example, by copolymerization of an unsaturated carboxylic acid and an ethylenically unsaturated compound. Examples of the unsaturated carboxylic acid include acrylic acid, methacrylic acid, maleic acid, fumaric acid, vinylacetic acid, and anhydrides thereof. On the other hand, examples of the ethylenically unsaturated compound include acrylic acid esters, such as methyl acrylate and ethyl acrylate; methacrylic acid esters, such as methyl methacrylate and ethyl methacrylate; and fumaric acid esters, such as monoethyl fumarate.

Furthermore, as the acrylic copolymer having a carboxyl group at a side chain thereof, an acrylic copolymer into which an unsaturated bond is introduced, as described below, may be used.

1) To a carboxyl group at a side chain of an acrylic copolymer, an acrylic monomer having a functional group, such as an epoxy group, capable of reacting with the carboxyl group is added.

2) An unsaturated monocarboxylic acid is made to react with the acrylic copolymer in which an epoxy group has been introduced instead of the carboxyl group at the side chain, and then a saturated or unsaturated polycarboxylic acid anhydride is introduced thereinto.

Furthermore, preferably, the acrylic copolymer having a carboxyl group at a side chain thereof has a weight-average molecular weight (Mw) of 50,000 or less and an acid value of 30 or more and 150 or less (i.e., from 30 to 150).

As the photosensitive monomer, for example, dipentaerythritol monohydroxy pentaacrylate can be used. Other examples of the photosensitive monomer which can be used include hexanediol triacrylate, tripropylene glycol triacrylate, trimethylolpropane triacrylate, EO-modified trimethylolpropane triacrylate, stearyl acrylate, tetrahydrofurfuryl acrylate, lauryl acrylate, 2-phenoxyethyl acrylate, isodecyl acrylate, iso-octyl acrylate, tridecyl acrylate, caprolactone acrylate, ethoxylated nonyl phenol acrylate, 1,3-butanediol diacrylate, 1,4-butanediol diacrylate, diethylene glycol diacrylate, tetraethylene glycol diacrylate, triethylene glycol diacrylate, ethoxylated bisphenol A diacrylate, propoxylated neopentyl glycol diacrylate, tris(2-hydroxyethyl) isocyanurate triacrylate, pentaerythritol triacrylate, propoxylated trimethylolpropane triacrylate, propoxylated glyceryl triacrylate, pentaerythritol tetraacrylate, di-trimethylolpropane tetraacrylate, and ethoxylated pentaerythritol tetraacrylate. Furthermore, the above-described compounds whose acrylate in the molecule is partially or entirely replaced by methacrylate may be used.

As the photopolymerization initiator, for example, 2-methyl-1-(4-methylthiophenyl)-2-morpholinopropan-1-one can be used. Other examples of the photopolymerization initiator which can be used include benzyl, benzoin ethyl ether, benzoin isobutyl ether, benzoin isopropyl ether, benzophenone, benzoylbenzoic acid, methyl benzoylbenzoate, 4-benzoyl-4′-methyldiphenyl sulfide, benzyl dimethyl ketal, 2-n-butoxy-4-dimethylamino benzoate, 2-chlorothioxanthone, 2,4-diethyl thioxanthone, 2,4-diisopropyl thioxanthone, isopropyl thioxanthone, 2-dimethylaminoethyl benzoate, p-dimethylamino ethyl benzoate, p-dimethylamino isoamyl benzoate, 3,3′-dimethyl-4-methoxybenzophenone, 2,4-dimethyl thioxanthone, 1-(4-dodecylphenyl)-2-hydroxy-2-methylpropan-1-one, 2,2-dimethoxy-1,2-diphenylethan-1-one, hydroxycyclohexyl phenyl ketone, 2-hydroxy-2-methyl-1-phenylpropan-1-one, 1-[4-(2-hydroxyethoxy)-phenyl]-2-hydroxy-2-methyl-1-propan-1-one, methyl benzoylformate, 1-phenyl-1,2-propanedione-2-(o-ethoxycarbonyl)oxime, 2-benzyl-2-dimethylamino-1-(4-morpholinophenyl)-1-butanone, bis(2,6-dimethoxybenzoyl)-2,4,4-trimethylpentyl phosphine oxide, and bis(2,4,6-trimethylbenzoyl)phenylphosphine oxide.

The photosensitive conductive paste according to the present disclosure preferably contains a solvent as a photosensitive organic component. In addition, the photosensitive conductive paste may contain a sensitizer, a defoaming agent, and the like. Regarding the solvent, the sensitizer, and the defoaming agent, various types can be used without particular restriction. The photosensitive conductive paste according to the present disclosure may further contain additives, such as a dispersant and an anti-settling agent.

[Method for Manufacturing Multilayer Electronic Component]

A method for manufacturing a multilayer electronic component according to the present disclosure includes a step of integrally firing a multilayer body which includes a conductor layer formed by using the photosensitive conductive paste according to the present disclosure and an insulation layer formed by using a photosensitive insulating paste containing an insulating inorganic component and a photosensitive organic component.

An example of a method for manufacturing a multilayer printed circuit chip (multilayer electronic component) using a photosensitive conductive paste according to the present disclosure will be described below.

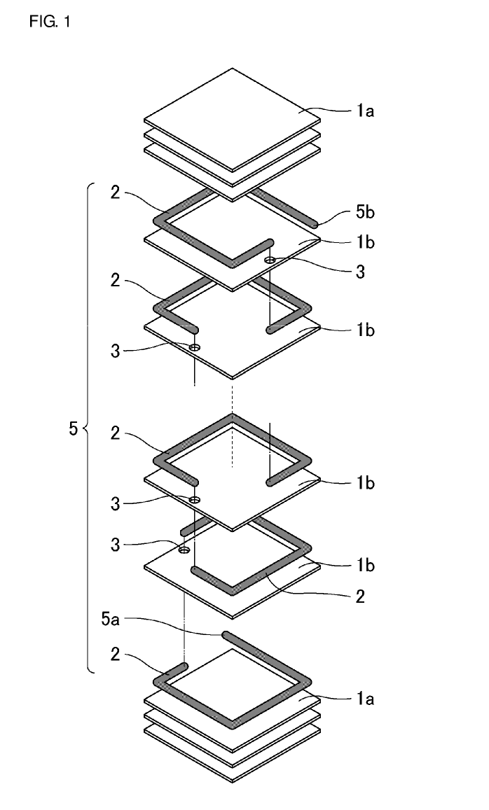

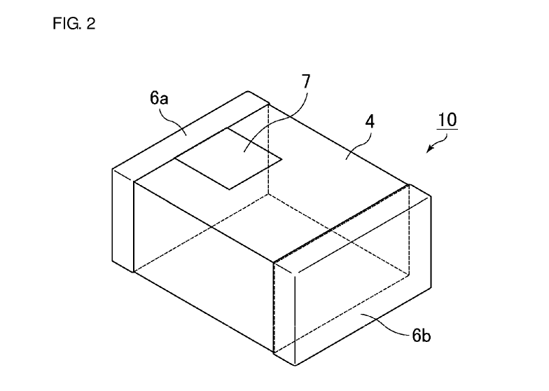

FIG. 1 is a perspective view schematically showing an example of a method for manufacturing a multilayer electronic component according to the present disclosure, and FIG. 2 is a perspective view schematically showing an external structure of a multilayer electronic component manufactured by the manufacturing method shown in FIG. 1.

A multilayer inductor will be described below as an example of the multilayer electronic component. However, the multilayer electronic component according to the present disclosure is not limited to multilayer coil components, such as multilayer inductors, but can be applied to various multilayer electronic components, such as multilayer ceramic boards and multilayer LC composite components.

First, a photosensitive glass paste serving as a photosensitive insulating paste is applied by screen printing onto a support film, such as a PET film, and dried, followed by exposure over the entire surface. This process is repeated several times to obtain an outer layer 1a, i.e., an insulation layer (glass layer), having a predetermined thickness (e.g., about 100 μm). Note that the support film is omitted in FIG. 1.

The photosensitive insulating paste, such as a photosensitive glass paste, contains an insulating inorganic component and a photosensitive organic component. The photosensitive glass paste contains, as insulating inorganic components, for example, a glass powder and a ceramic aggregate (ceramic filler), and contains, as photosensitive organic components, for example, an alkali-soluble polymer, a photosensitive monomer, and a photopolymerization initiator. In addition, the photosensitive insulating paste may further contain, as photosensitive organic components, a solvent, an organic dye, a defoaming agent, and the like.

The glass powder incorporated in the photosensitive insulating paste is not particularly limited. For example, a Si—B—K-based glass containing SiO₂, B₂O₃, and K₂O at predetermined ratios may be used. Two or more glass powders may be mixed for use. The average particle size of the glass powder is not particularly limited, but is preferably 0.8 μm or more and 1.3 μm or less (i.e., from 0.8 μm to 1.3 μm).

The ceramic aggregate incorporated in the photosensitive insulating paste is not particularly limited. For example, alumina can be used. Two or more ceramic aggregates may be mixed for use. The average particle size of the ceramic aggregate is not particularly limited, but is preferably 0.1 μm or more and 5.0 μm or less (i.e., from 0.1 μm to 5.0 μm).

The insulation layers including the outer layer may be formed by stacking green sheets which have been formed into a sheet shape in advance.

The photosensitive conductive paste according to the present disclosure is applied by screen printing onto the outer layer 1a with a film thickness of about 5 μm or more and about 10 μm or less (i.e., from about 5 μm to about 10 μm), and dried. Then, the photosensitive conductive paste is subjected to selective exposure and development to form a first conductor layer (coil pattern) 2.

The photosensitive glass paste is applied by screen printing over the entire surface so as to cover the first conductor layer (coil pattern) 2 with a film thickness of about 15 μm, and dried. Subsequently, the photosensitive glass paste is subjected to selective exposure and development, and a via hole 3 is formed at a predetermined position of a first insulation layer 1b.

The photosensitive conductive paste according to the present disclosure is again applied by screen printing over the entire surface with a film thickness of about 5 μm or more and about 10 μm or less (i.e., from about 5 μm to about 10 μm), and dried. Then, the photosensitive conductive paste is subjected to selective exposure and development to form a second conductor layer (coil pattern) 2.

Furthermore, an insulation layer 1b and a conductor layer 2 are repeatedly stacked until a desired number of layers is obtained.

Furthermore, by repeating a process of application by printing of the photosensitive glass paste over the entire surface, drying, and exposure over the entire surface a required number of times, an outer layer 1a is obtained. In this way, a multilayer structure in which conductor layers 2 are connected through via holes 3 is obtained.

As necessary, an orientation mark pattern 7 (refer to FIG. 2) for indicating the orientation of the chip is applied by screen printing onto an uppermost layer of the outer layer 1a.

The resulting multilayer structure is divided into chips by using a dicer, then the support film, such as a PET film, is removed, and firing is performed.

Outer electrodes 6a and 6b are formed on the fired multilayer body. Furthermore, a single or multilayered plating layer may be formed by electrolytic plating or non-electrolytic plating on the surface of each of the outer electrodes 6a and 6b.

In this way, a multilayer printed circuit chip (multilayer electronic component) 10 shown in FIG. 2 is obtained. The multilayer electronic component thus obtained is also an embodiment of the present disclosure.

[Multilayer Electronic Component]

A multilayer electronic component according to the present disclosure includes conductor layers obtained by firing the photosensitive conductive paste according to the present disclosure, the conductor layers being stacked together with an insulation layer obtained by firing a photosensitive insulating paste containing an insulating inorganic component and a photosensitive organic component interposed therebetween.

A multilayer printed circuit chip (multilayer electronic component) 10 shown in FIG. 2 includes a multilayer body 4 in which, as shown in FIG. 1, conductor layers 2 formed by using the photosensitive conductive paste according to the present disclosure are stacked together with an insulation layer 1b formed by using a photosensitive insulating paste, such as a photosensitive glass paste, interposed therebetween, conductor layers 2 are connected together through via holes 3, and thus a structure having a helical coil 5 disposed therein is formed.

In FIG. 2, outer electrodes 6a and 6b are disposed on left and right ends of the multilayer body 4 so as to be electrically connected to end portions 5a and 5b of the coil 5, respectively. An orientation mark pattern 7 for indicating the orientation of the multilayer inductor 10 is disposed on the upper surface of the multilayer body 4. It is not always necessary to dispose an orientation mark pattern 7 thereon.

### Examples

Examples which more specifically disclose the photosensitive conductive paste according to the present disclosure will be shown below. Note that the present disclosure is not limited to these examples only.

[Preparation of Photosensitive Conductive Paste]

The raw materials shown in Table 1 were compounded in proportions shown below and thoroughly mixed to obtain a photosensitive resin as a photosensitive organic component.

TABLE 1

| | Content in photosensitive resin |
|---|---|
| Composition | (parts by weight) |
| Alkali-soluble polymer | 39.1 |
| (acrylic polymer having a carboxyl | |
| group at a side chain thereof) | |
| Photosensitive monomer | 17.5 |
| (dipentaerythritol monohydroxy | |
| pentaacrylate) | |
| Photopolymerization initiator | 4.0 |
| (2-methyl-1-(4-methylthiophenyl)- | |
| 2-morpholinopropan-1-one) | |
| Sensitizer | 0.4 |
| (2,4-diethyl thioxanthone) | |
| Solvent | 37.9 |
| (dipropylene glycol | |
| monomethyl ether) | |
| Defoaming agent | 1.1 |

A metal powder (Ag powder or Cu powder with an average particle size of 3.0 μm), a metal resinate, the photosensitive resin, a dispersant (additive A), and an anti-settling agent (additive B) were compounded in proportions shown in Table 3 or 4 and thoroughly mixed by using a three-roll mill. In this way, photosensitive conductive pastes for forming conductor layers were obtained.

[Preparation of Photosensitive Glass Paste]

The raw materials shown in Table 2 were compounded in proportions shown below and thoroughly mixed by using a three-roll mill to obtain a photosensitive glass paste for forming insulation layers.

TABLE 2

| | Content in paste |
|---|---|
| Composition | (parts by weight) |
| Alkali-soluble polymer | 28 |
| (acrylic polymer having a carboxyl group | |
| at a side chain thereof) | |
| Photosensitive monomer | 12 |
| (EO-modified trimethylolpropane triacrylate) | |
| Photopolymerization initiator | 2 |
| (2-methyl-1-(4-methylthiophenyl)-2- | |
| morpholinopropan-1-one) | |
| Solvent | 0.6 |
| (pentamethylene glycol) | |
| Organic dye | 1 |
| Defoaming agent | 1 |
| Glass powder (Si—B—K-based glass) | 34 |
| (glass softening point: 790° C., average | |
| particle size: 1.1 μm) | |
| Ceramic aggregate (alumina) | 21.4 |
| (average particle size: 0.5 μm) | |

[Fabrication of Multilayer Printed Circuit Chip (Multilayer Electronic Component)]

By using the thus prepared photosensitive conductive paste and photosensitive glass paste, a multilayer printed circuit chip (multilayer electronic component) was fabricated by the method described below.

First, the photosensitive glass paste was applied by screen printing onto a PET film, and dried, followed by exposure over the entire surface. This process was repeated several times to obtain an outer layer, i.e., an insulation layer (glass layer), having a thickness of about 100 μm.

The photosensitive conductive paste was applied by screen printing onto the outer layer with a film thickness of about 10 μm, and dried. Then, the photosensitive conductive paste was subjected to selective exposure and development to form a first conductor layer (coil pattern).

The photosensitive glass paste was applied by screen printing over the entire surface so as to cover the first conductor layer (coil pattern) with a film thickness of about 15 μm, and dried. Subsequently, the photosensitive glass paste was subjected to selective exposure and development, and a via hole was formed at a predetermined position of a first insulation layer.

The photosensitive conductive paste was again applied by screen printing over the entire surface with a film thickness of about 10 μm, and dried. Then, the photosensitive conductive paste was subjected to selective exposure and development to form a second conductor layer (coil pattern).

Furthermore, an insulation layer and a conductor layer were repeatedly stacked until a desired number of conductor layers was obtained.

Furthermore, by repeating a process of application by printing of the photosensitive glass paste over the entire surface, drying, and exposure over the entire surface a required number of times, an outer layer with a thickness of about 100 μm was obtained. In this way, a multilayer structure in which conductor layers are connected through via holes was obtained.

The resulting multilayer structure was divided into chips having a size of about 0.5 mm square by using a dicer, then the PET film was removed, and firing was performed. By the method described above, a multilayer printed circuit chip (multilayer electronic component) was fabricated.

[Evaluation]

(1) Delamination Occurrence Rate

Regarding 100 multilayer printed circuit chips fabricated by using each of the photosensitive conductive pastes, a cross section of the middle of the chip was observed with a microscope (VHX-900 manufactured by KEYENCE Corporation). When a gap with a thickness of 10 μm was observed between a coil pattern and an insulation layer in a multilayer printed circuit chip, the chip was counted as a chip with delamination.

The delamination occurrence rate was calculated in accordance with the formula below. The results thereof are shown in Tables 3 and 4.

Delamination occurrence rate (%)=(number of chips with delamination/100)×100

(2) Resolution

The resolution when forming a coil pattern by using each of the photosensitive conductive pastes was evaluated in the following manner. Each of the photosensitive conductive pastes was applied by screen printing onto an insulation layer (hardened photosensitive glass film) formed by using the photosensitive glass paste, and then dried at 60° C. for 30 minutes to thereby form a photosensitive conductive paste film having a film thickness of 5 to 8 μm. Next, the photosensitive conductive paste film was subjected to exposure, through a mask depicted with a line width/space width of 2/2 to 50/50 μm, by irradiation with light from an ultra-high pressure mercury lamp at 600 mJ/cm². Then, by performing development with an aqueous triethanolamine solution, conductive patterns were obtained.

The obtained conductive patterns were observed, and the width of the finest conductive pattern obtained without missing lines or space residues was considered as the resolution of each sample. Note that the “width of the finest conductive pattern” means the width of the line formed on the mask corresponding to this conductive pattern. The results thereof are shown in Tables 3 and 4.

In Table 4, regarding the resolution, the evaluation “Missing” means that the entire photosensitive conductive paste film (i.e., all the lines with widths of 2 to 50 μm) was lost during development. This occurs because, when the exposure is performed, the light does not reach the bottom of the photosensitive conductive paste film, the photosensitive conductive paste film does not harden in the area near the boundary with the insulation layer, and therefore, the photosensitive conductive paste film (lines) is lost during development.

TABLE 3

| | | Example 1 | Example 2 | Example 3 | Example 4 | Example 5 | Example 6 | Example 7 | Example 8 |
|---|---|---|---|---|---|---|---|---|---|
| Metal | Ag powder | 80.000 | 80.000 | 80.000 | 80.000 | 80.000 | 80.000 | 80.000 | 80.000 |
| powder | Cu powder | — | — | — | — | — | — | — | — |
| (wt %) | | | | | | | | | |
| Metal | Rh resinate | 0.020 | 0.040 | 0.080 | 0.160 | 0.320 | 0.800 | 4.000 | 8.000 |
| resinate | Ni resinate | — | — | — | — | — | — | — | — |
| (wt %) | Cu resinate | — | — | — | — | — | — | — | — |
| | Mn resinate | — | — | — | — | — | — | — | — |
| | Zr resinate | — | — | — | — | — | — | — | — |
| | Sn resinate | — | — | — | — | — | — | — | — |
| | Al resinate | — | — | — | — | — | — | — | — |

| Photosensitive resin (wt %) | 19.580 | 19.560 | 19.520 | 19.440 | 19.280 | 18.800 | 15.600 | 11.600 |
|---|---|---|---|---|---|---|---|---|
| Additive A (wt %) | 0.200 | 0.200 | 0.200 | 0.200 | 0.200 | 0.200 | 0.200 | 0.200 |
| Additive B (wt %) | 0.200 | 0.200 | 0.200 | 0.200 | 0.200 | 0.200 | 0.200 | 0.200 |
| Total | 100 | 100 | 100 | 100 | 100 | 100 | 100 | 100 |
| Metal contained in resinate | Rh | Rh | Rh | Rh | Rh | Rh | Rh | Rh |
| Content of metal resinate, in | 0.0025 | 0.0050 | 0.0100 | 0.0200 | 0.0400 | 0.1000 | 0.5000 | 1.0000 |
| terms of metal | | | | | | | | |
| (wt % vs metal powder) | | | | | | | | |
| Melting point of metal | 1963 | | | | | | | |
| resinate (° C.) | | | | | | | | |
| Difference in melting point | 1001 | | | | | | | |
| from metal powder (° C.) | | | | | | | | |
| Delamination occurrence rate | 6 | 0 | 0 | 0 | 0 | 0 | 0 | 0 |
| (%) | | | | | | | | |
| Resolution (μm) | 6 | 8 | 8 | 8 | 10 | 18 | 36 | 48 |

| | | | Example | Example | Example | Example | Example | Example |
|---|---|---|---|---|---|---|---|---|
| | | Example 9 | 10 | 11 | 12 | 13 | 14 | 15 |
| Metal | Ag powder | 68.000 | 88.000 | 80.000 | 80.000 | 80.000 | 80.000 | — |
| powder | Cu powder | — | — | — | — | — | — | 80.000 |
| (wt %) | | | | | | | | |
| Metal | Rh resinate | 0.680 | 0.088 | — | — | — | — | 0.160 |
| resinate | Ni resinate | — | — | 0.320 | — | — | — | — |
| (wt %) | Cu resinate | — | — | — | 0.400 | — | — | — |
| | Mn resinate | — | — | — | — | 0.400 | — | — |
| | Zr resinate | — | — | — | — | — | 0.218 | — |
| | Sn resinate | — | — | — | — | — | — | — |
| | Al resinate | — | — | — | — | — | — | — |

| Photosensitive resin (wt %) | 30.920 | 11.512 | 19.280 | 19.200 | 19.200 | 19.382 | 19.440 |
|---|---|---|---|---|---|---|---|
| Additive A (wt %) | 0.200 | 0.200 | 0.200 | 0.200 | 0.200 | 0.200 | 0.200 |
| Additive B (wt %) | 0.200 | 0.200 | 0.200 | 0.200 | 0.200 | 0.200 | 0.200 |
| Total | 100 | 100 | 100 | 100 | 100 | 100 | 100 |
| Metal contained in resinate | Rh | Rh | Ni | Cu | Mn | Zr | Rh |
| Content of metal resinate, in | 0.1000 | 0.1000 | 0.0400 | 0.0400 | 0.0400 | 0.0400 | 0.0200 |
| terms of metal | | | | | | | |
| (wt % vs metal powder) | | | | | | | |
| Melting point of metal | 1963 | | 1453 | 1083 | 1244 | 1852 | 1963 |
| resinate (° C.) | | | | | | | |
| Difference in melting point | 1001 | | 491 | 121 | 282 | 890 | 880 |
| from metal powder (° C.) | | | | | | | |
| Delamination occurrence rate | 42 | 0 | 0 | 0 | 0 | 0 | 0 |
| (%) | | | | | | | |
| Resolution (μm) | 6 | 20 | 10 | 10 | 10 | 10 | 10 |

TABLE 4

| | | Comparative | Comparative | Comparative | Comparative | Comparative | Comparative | Comparative |
|---|---|---|---|---|---|---|---|---|
| | | Example 1 | Example 2 | Example 3 | Example 4 | Example 5 | Example 6 | Example 7 |
| Metal powder | Ag powder | 80.000 | 80.000 | 80.000 | 80.000 | 80.000 | 65.000 | 90.000 |
| (wt %) | Cu powder | — | — | — | — | — | — | — |
| Metal resinate | Rh resinate | — | 0.008 | 12.000 | — | — | 0.650 | 0.090 |
| (wt %) | Ni resinate | — | — | — | — | — | — | — |
| | Cu resinate | — | — | — | — | — | — | — |
| | Mn resinate | — | — | — | — | — | — | — |
| | Zr resinate | — | — | — | — | — | — | — |
| | Sn resinate | — | — | — | 0.128 | — | — | — |
| | Al resinate | — | — | — | — | 0.320 | — | — |

| | | | | | | | |
|---|---|---|---|---|---|---|---|
| Photosensitive resin (wt %) | 19.600 | 19.592 | 7.600 | 19.472 | 19.280 | 33.950 | 9.510 |
| Additive A (wt %) | 0.200 | 0.200 | 0.200 | 0.200 | 0.200 | 0.200 | 0.200 |
| Additive B (wt %) | 0.200 | 0.200 | 0.200 | 0.200 | 0.200 | 0.200 | 0.200 |
| Total | 100 | 100 | 100 | 100 | 100 | 100 | 100 |
| Metal contained in resinate | — | Rh | Rh | Sn | Al | Rh | Rh |
| Content of metal resinate, in terms of metal | — | 0.0010 | 1.5000 | 0.0400 | 0.0400 | 0.1000 | 0.0100 |
| (wt % vs metal powder) | | | | | | | |
| Melting point of metal resinate (° C.) | — | 1963 | 1963 | 232 | 660 | 1963 | 1963 |
| Difference in melting point from metal powder | — | 1001 | 1001 | −730 | −302 | 1001 | 1001 |
| (° C.) | | | | | | | |
| Delamination occurrence rate (%) | 100 | 100 | 0 | 100 | 100 | 100 | 0 |
| Resolution (μm) | 6 | 6 | Missing | 10 | 10 | 6 | Missing |

Tables 3 and 4 confirm that, in Examples 1 to 15, each containing a metal resinate containing a metal having a higher melting point than the metal powder, in comparison with Comparative Example 1 not containing a metal resinate and Comparative Examples 4 and 5, each containing a metal resinate containing a metal having a lower melting point than the metal powder, the delamination occurrence rate greatly decreases.

The results of Examples 1 to 8 confirm that in the case where the content of the metal resinate, in terms of metal, with respect to the metal powder is 0.0025% by weight or more and 1.0% by weight or less (i.e., from 0.0025% by weight to 1.0% by weight), an effect of suppressing delamination is exhibited, and in the case of 0.005% by weight or more, the effect of suppressing delamination is high.

The results also confirm that, although the resolution tends to decrease as the content of the metal resinate increases, if the content of the metal resinate is 0.0025% by weight or more and 1.0% by weight or less (i.e., from 0.0025% by weight to 1.0% by weight), a conductive pattern with a line width of 50 μm or less can be formed. In particular, it is considered that, while suppressing delamination, in order to form a conductive pattern with a line width of 40 μm or less, the content of the metal resinate is preferably 0.5% by weight or less, in order to form a conductive pattern with a line width of 20 μm or less, the content of the metal resinate is preferably 0.1% by weight or less, and in order to form a conductive pattern with a line width of 10 μm or less, the content of the metal resinate is preferably 0.04% by weight or less.

In contrast, the results confirm that, in Comparative Example 2 in which the content of the metal resinate is less than 0.0025% by weight, the occurrence rate of delamination due to an insufficient effect of suppressing firing shrinkage increases, and in Comparative Example 3 in which the content of the metal resinate is more than 1.0% by weight, missing conductive patterns due to interception of light occur.

The results of Examples 9 and 10 confirm that, if the content of the metal powder in the photosensitive conductive paste is 68% by weight or more and 88% by weight or less (i.e., from 68% by weight to 88% by weight), suppression of occurrence of delamination and high resolution can be achieved. In contrast, the results confirm that, in Comparative Example 6 in which the amount of the metal powder is small, even when the metal resinate is incorporated, shrinkage during firing increases, resulting in an increase in the delamination occurrence rate, and in Comparative Example 7 in which the amount of the metal powder is large, missing conductive patterns due to interception of light occur.

The present disclosure is not limited to the above-described embodiments and examples and may be used in various applications and may be modified in various ways, in terms of the properties of a metal powder, the composition of a photosensitive organic component, types of materials constituting an insulation layer, and the like, within the scope of the present disclosure.

What is claimed is:

1. A photosensitive conductive paste comprising:
a metal powder;
a metal resinate containing a metal having a higher melting point than the metal powder; and
a photosensitive organic component,
wherein
a content of the metal resinate, in terms of metal, with respect to the metal powder is from 0.0025% by weight to 1.0% by weight, and
a content of the metal powder in the photosensitive conductive paste is from 68% by weight to 88% by weight.

2. The photosensitive conductive paste according to claim 1, wherein the metal powder is a Ag powder or Cu powder.

3. The photosensitive conductive paste according to claim 1, wherein a difference between a melting point of the metal contained in the metal resinate and a melting point of the metal powder is 121° C. or more.

4. The photosensitive conductive paste according to claim 1, wherein the metal contained in the metal resinate is one selected from the group consisting of Rh, Ni, Cu, Mn, and Zr.

5. The photosensitive conductive paste according to claim 1, wherein the content of the metal powder in the photosensitive conductive paste is from 80% by weight to 88% by weight.

6. The photosensitive conductive paste according to claim 1, wherein the content of the metal resinate, in terms of metal, with respect to the metal powder is 0.005% by weight or more.

7. The photosensitive conductive paste according to claim 1, wherein the content of the metal resinate, in terms of metal, with respect to the metal powder is 0.5% by weight or less.

8. The photosensitive conductive paste according to claim 1, wherein the content of the metal resinate, in terms of metal, with respect to the metal powder is 0.1% by weight or less.

9. The photosensitive conductive paste according to claim 1, wherein the content of the metal resinate, in terms of metal, with respect to the metal powder is 0.04% by weight or less.

10. A method for manufacturing a multilayer electronic component comprising a step of integrally firing a multilayer body which includes a conductor layer formed by using the photosensitive conductive paste according to claim 1, and an insulation layer formed by using a photosensitive insulating paste containing an insulating inorganic component and a photosensitive organic component.

11. A multilayer electronic component comprising conductor layers obtained by firing the photosensitive conductive paste according to claim 1, the conductor layers being stacked together with an insulation layer obtained by firing a photosensitive insulating paste containing an insulating inorganic component and a photosensitive organic component interposed therebetween.

12. The photosensitive conductive paste according to claim 2, wherein a difference between a melting point of the metal contained in the metal resinate and a melting point of the metal powder is 121° C. or more.

13. The photosensitive conductive paste according to claim 2, wherein the metal contained in the metal resinate is one selected from the group consisting of Rh, Ni, Cu, Mn, and Zr.

14. The photosensitive conductive paste according to claim 2, wherein the content of the metal powder in the photosensitive conductive paste is from 80% by weight to 88% by weight.

15. The photosensitive conductive paste according to claim 2, wherein the content of the metal resinate, in terms of metal, with respect to the metal powder is 0.005% by weight or more.

16. The photosensitive conductive paste according to claim 2, wherein the content of the metal resinate, in terms of metal, with respect to the metal powder is 0.5% by weight or less.

17. The photosensitive conductive paste according to claim 2, wherein the content of the metal resinate, in terms of metal, with respect to the metal powder is 0.1% by weight or less.

18. The photosensitive conductive paste according to claim 2, wherein the content of the metal resinate, in terms of metal, with respect to the metal powder is 0.04% by weight or less.

19. A method for manufacturing a multilayer electronic component comprising a step of integrally firing a multilayer body which includes a conductor layer formed by using the photosensitive conductive paste according to claim 2, and an insulation layer formed by using a photosensitive insulating paste containing an insulating inorganic component and a photosensitive organic component.

20. A multilayer electronic component comprising conductor layers obtained by firing the photosensitive conductive paste according to claim 2, the conductor layers being stacked together with an insulation layer obtained by firing a photosensitive insulating paste containing an insulating inorganic component and a photosensitive organic component interposed therebetween.
